(19) United States
(12) Patent Application Publication
(10) Pub. No.: US 2025/0386738 A1
(43) Pub. Date: Dec. 18, 2025

(54) MRAM STRUCTURE AND FABRICATING METHOD OF THE SAME

(71) Applicant: UNITED MICROELECTRONICS CORP., Hsin-Chu City (TW)

(72) Inventor: Ching-Hua Hsu, Kaohsiung City (TW)

(73) Assignee: UNITED MICROELECTRONICS CORP., Hsin-Chu City (TW)

(21) Appl. No.: 18/774,920

(22) Filed: Jul. 17, 2024

(30) Foreign Application Priority Data
Jun. 17, 2024 (TW) 113122263

(51) Int. Cl. H10N 50/80; G11C 11/16; H10B 61/00; H10N 50/01; H10N 50/10

(52) U.S. Cl. CPC H10N 50/80; G11C 11/161; H10B 61/00; H10N 50/01; H10N 50/10

(57) ABSTRACT

An MRAM structure includes a first dielectric layer, and the first dielectric layer is divided into a memory region and a logic circuit region. An MRAM is embedded in the memory region of the first dielectric layer. The MRAM includes a bottom electrode, an MTJ and a top electrode stacked in sequence from bottom to top. A conductive plug is disposed on the top electrode and contacts the top electrode. The diameter of the conductive plug is smaller than the diameter of the MTJ. The conductive plug overlaps only one MRAM. A first metal interconnect structure is embedded in the logic circuit region of the first dielectric layer. The first metal interconnect structure includes a contact plug and a conductive line. The conductive line is disposed on the contact plug, and the top surface of the conductive line is aligned with the top surface of the conductive plug.

### BACKGROUND OF THE INVENTION

### 1. Field of the Invention

The present invention relates to a structure of a magnetoresistive random access memory (MRAM) and a fabricating method thereof. In particular, the present invention relates to a fabricating method which prevents damage to the MRAM structure during the formation of metal interconnections.

### 2. Description of the Prior Art

Many modern day electronic devices contain electronic memory configured to store data. Electronic memory may be volatile memory or non-volatile memory. Volatile memory stores data only while it is powered, while non-volatile memory is able to store data even when power is removed. MRAM is one promising candidate for next generation non-volatile memory technology.

An MTJ generally includes a layered structure comprising a reference layer, a free layer and a tunnel oxide in between. The reference layer of magnetic material has a magnetic moment that always points in the same direction. The magnetic moment of the free layer is free, but is determined by the physical dimensions of the element. The magnetic moment of the free layer points in either of two directions: parallel or anti-parallel to the magnetization direction of the reference layer.

However, the conventional MRAM process still has many shortcomings that need further improvement. For example, the fabrication of metal interconnections that electrically connect the MRAM will damage the MRAM and affect the electrical properties of MRAM. Therefore, an improved MRAM manufacturing method and structure to solve the aforementioned problem is needed.

### SUMMARY OF THE INVENTION

In view of this, the present invention provides a novel method for fabricating an MRAM structure to prevent the MRAM structure from being damaged during the fabricating process.

According to a preferred embodiment of the present invention, an MRAM structure includes a first dielectric layer, wherein the first dielectric layer is divided into a memory region and a logic circuit region. An MRAM is embedded in the memory region of the first dielectric layer, wherein the MRAM includes a bottom electrode, a magnetic tunnel junction (MTJ) and a top electrode stacked in sequence from bottom to top. A conductive plug is disposed on the top electrode and contacts the top electrode, wherein a diameter of the conductive plug is smaller than a diameter of the MTJ, and the conductive plug overlaps only one MRAM. A first metal interconnect structure is embedded in the logic circuit region of the first dielectric layer, wherein the first metal interconnect structure includes a contact plug and a conductive line, the conductive line is disposed on the contact plug, and a top surface of the conductive line is aligned with a top surface of the conductive plug.

According to another preferred embodiment of the present invention, a fabricating method of an MRAM structure includes providing a first dielectric layer, wherein the first dielectric layer is divided into a memory region and a logic circuit region, an MRAM is embedded in the memory region of the first dielectric layer, and the MRAM includes a bottom electrode, an MTJ and a top electrode stacked in sequence from bottom to top. Later, the first dielectric layer is etched to form a first contact hole and a second contact hole in the first dielectric layer, wherein the first contact hole is disposed in the memory region and the top electrode is exposed through the first contact hole, the second contact hole is disposed in the logic circuit region, a diameter of the first contact hole is smaller than a diameter of the top electrode, and a boundary of the first contact hole does not exceed a boundary of the top electrode. After that, the first dielectric layer is etched to form a trench in the logic circuit region of the first dielectric layer, wherein the trench is connected to the second contact hole, the trench is disposed on the second contact hole. Finally, a conductive material is formed to fill the first contact hole, the trench and the second contact hole to form a conductive plug and a first metal interconnect structure, wherein the conductive plug contacts the top electrode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2A, FIG. 3, FIG. 5 and FIG. 7 depict a fabricating process of an MRAM structure according to a preferred embodiment of the present invention, wherein:

FIG. 2A depicts a fabricating stage in continuous of FIG. 1;

FIG. 3 depicts a fabricating stage in continuous of FIG. 2A;

FIG. 5 depicts a fabricating stage in continuous of FIG. 3; and

FIG. 7 depicts a fabricating stage in continuous of FIG. 5.

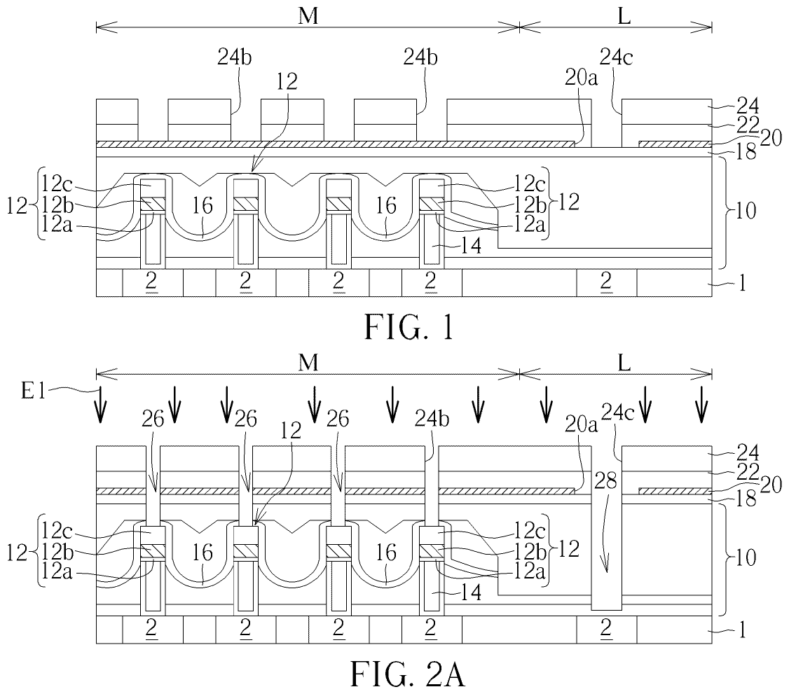

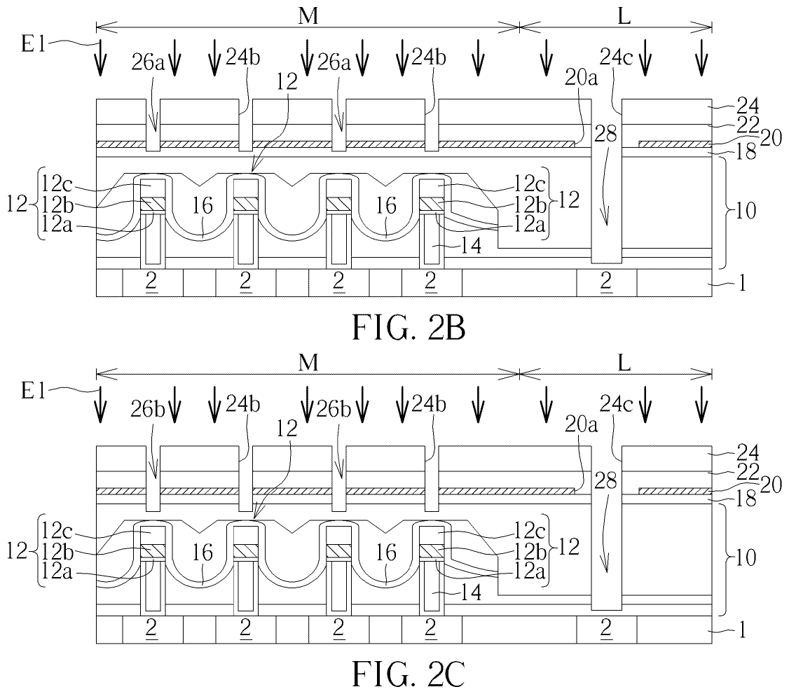

FIG. 2B depicts a fabricating method of an MRAM structure according to another preferred embodiment of the present invention.

FIG. 2C depicts a fabricating method of an MRAM structure according to yet another preferred embodiment of the present invention.

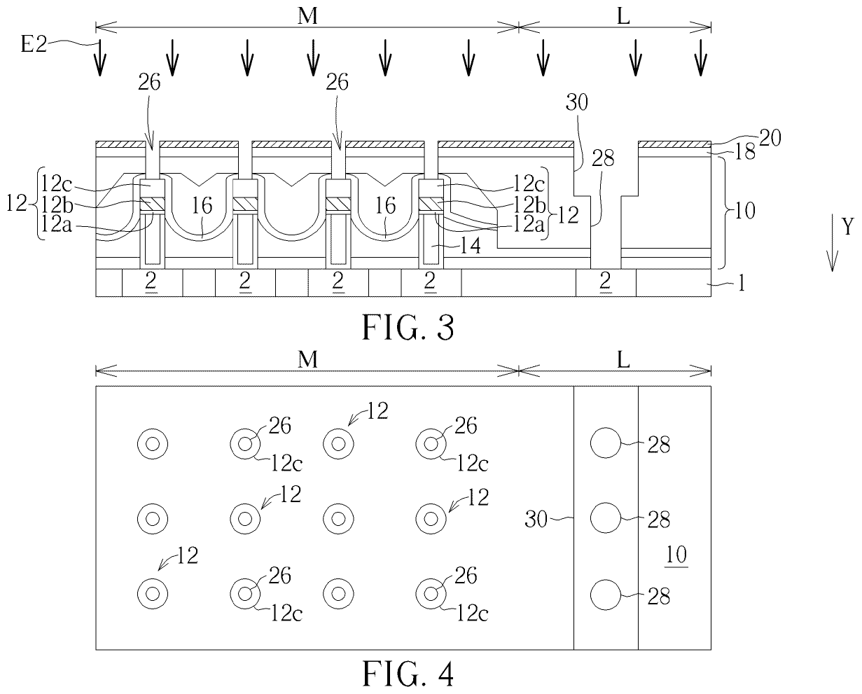

FIG. 4 depicts a top view of FIG. 3 according to a preferred embodiment of the present invention.

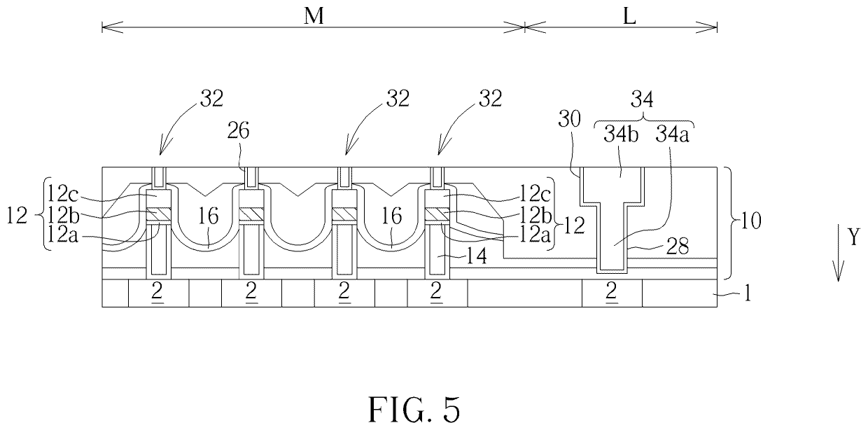

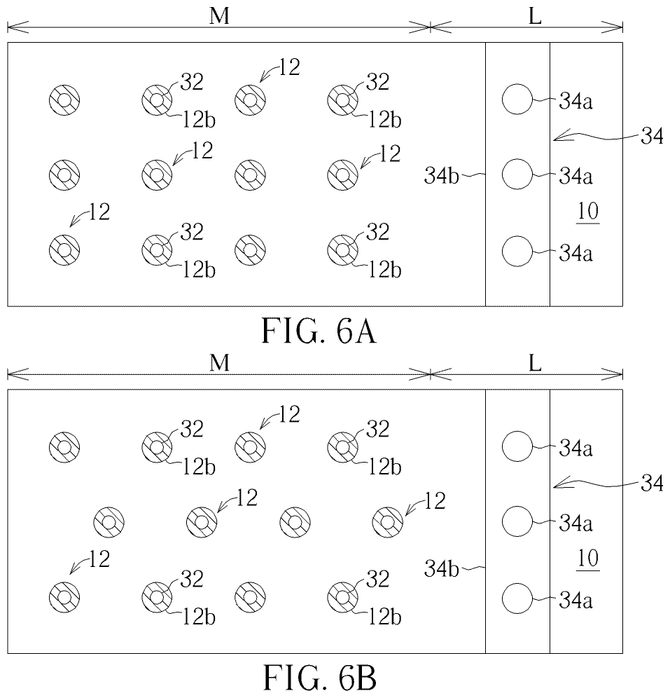

FIG. 6A depicts a top view of FIG. 5 according to a preferred embodiment of the present invention.

FIG. 6B depicts a top view of FIG. 5 according to another preferred embodiment of the present invention.

### DETAILED DESCRIPTION

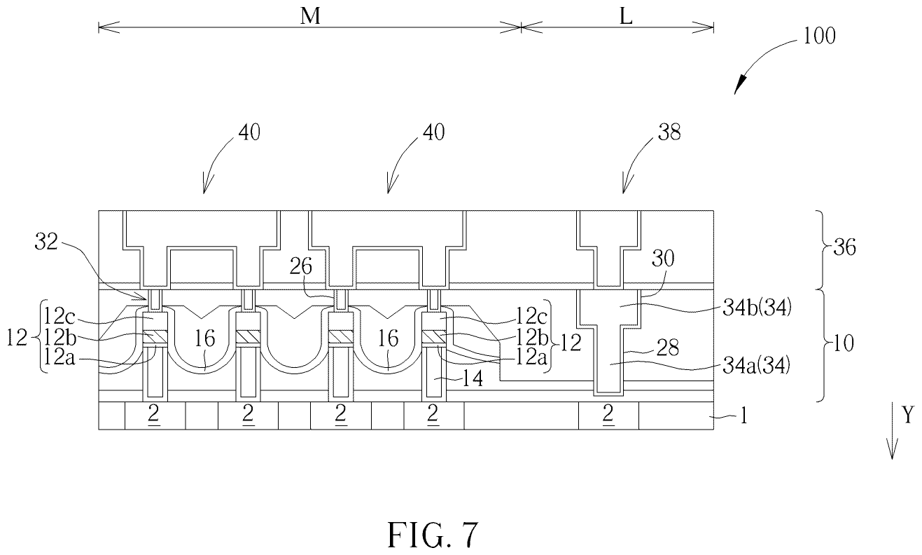

FIG. 1, FIG. 2A, FIG. 3, FIG. 5 and FIG. 7 depict a fabricating process of an MRAM structure according to a preferred embodiment of the present invention.

As shown in FIG. 1, a dielectric layer 1 is provided. The dielectric layer 1 can be an insulating material such as silicon nitride, silicon oxide, silicon oxynitride, etc. Numerous metal lines 2 are disposed in the dielectric layer 1. The metal lines 2 include tungsten, aluminum or copper. Each metal line 2 can be electrically connected to an active device, such as a transistor (not shown). Later, a first dielectric layer 10 is provided. The first dielectric layer 10 is preferably a material with a low dielectric constant, such as an insulating material with a dielectric constant less than 4. For example, the first dielectric layer 10 may be SiOC:H, fluorosilicone glass (FSG), etc. The first dielectric layer 10 covers and contacts the dielectric layer 1. The first dielectric layer 10 is divided into a memory region M and a logic circuit region L. At least one MRAM 12 is embedded in the memory region M of the first dielectric layer 10. In this embodiment, four MRAMs 12 are taken as an example, but not limited to this number. Each MRAM 12 includes a bottom electrode 12a, a magnetic tunnel junction (MTJ) 12b and a top electrode 12c stacked in sequence from bottom to top. The top electrode 12c and the bottom electrode 12a may include titanium nitride, tantalum nitride, or other conductive materials. The MTJ 12b includes several layers of ferromagnetic material and at least one insulating layer disposed between the adjacent ferromagnetic materials. A conductive plug 14 such as a tungsten plug is disposed below each MRAM 12. The conductive plug 14 contacts both the metal line 2 and the MRAM 12. Moreover, a spacer 16 surrounds the top surface and the sidewall of each MRAM 12. The spacer 16 extends from the sidewall of one MRAM 12 to the sidewall of another adjacent MRAM 12. The spacer 16 can be made of insulating materials such as silicon nitride.

Later, a first hard mask 18 and a second hard mask 20 are formed in sequence to cover the first dielectric layer 10 from bottom to top. The first hard mask 18 is preferably silicon oxynitride, and the second hard mask 20 is preferably titanium nitride. After that, the second hard mask 20 is patterned to form a first opening 20a in the second hard mask 20 located in the logic circuit region L. The first opening 20a defines the location of the conductive lines of the dual damascene structure which will be formed afterwards. After patterning the second hard mask 20, a mask layer 22 and a photoresist layer 24 are formed to cover the second hard mask 20 from bottom to top, and the mask layer 22 fills the first opening 20a. The mask layer 22 preferably includes an organic dielectric layer (ODL) (not shown) and a silicon-containing hard mask bottom anti-reflective coating (SHB) (not shown). The SHB is disposed on the ODL. The photoresist layer 24 is then patterned to form at least one second opening 24b and one third opening 24c in the photoresist layer 24. Each second opening 24b corresponds to one MRAM 12, and the third opening 24c corresponds to the first opening 20a. The width of the first opening 20a is larger than the width of the third opening 24c. The second opening 24b defines the position of a conductive plug which will be formed on the MRAM 12, and the third opening 24c defines the position of a contact plug of a dual damascene structure which will be formed later.

As shown in FIG. 2A, after patterning the photoresist layer 24, a first etching E1 is performed. The first etching E1 includes using the photoresist layer 24 as a mask to etch the mask layer 22, the second hard mask 20, the first hard mask 18, the first dielectric layer 10 and the spacer 16 to form numerous first contact holes 26 and a second contact hole 28 in the dielectric layer 10. The first contact holes 26 are disposed in the memory region M, and the second contact hole 28 is located in the logic circuit region L. At this time, the top electrode 12c of each MRAM 12 is exposed through one of the first contact holes 26. The conductive line 2 disposed in the logic circuit region L is still covered by the first dielectric layer 10.

FIG. 4 depicts a top view of FIG. 3 according to a preferred embodiment of the present invention. As shown in FIG. 3 and FIG. 4, the photoresist layer 24 and mask layer 22 are completely removed. Later, a second etching E2 is performed. The second etching E2 includes using the second hard mask 20 as a mask to etch the first dielectric layer 10 to form a trench 30 in the logic circuit region of the first dielectric layer 10 and to make the conductive line 2 in the logic circuit region L exposed through the second contact hole 28. The trench 30 is connected to the second contact hole 28, and the trench 30 is located on the second contact hole 28. In details, because the first opening 20a is formed on the second hard mask 20, the sidewall of the second contact hole 28 exposed through the first opening 20a will be etched and then expanded to become the trench 30. Meanwhile, the first dielectric layer 10 disposed on the conductive line 2 in the logic circuit region L is also etched. It is noteworthy that a vertical direction Y is defined as a direction from the top electrode 12c to the bottom electrode 12a. When seeing along the vertical direction Y (please refer to FIG. 4), the bottom electrode 12a, the MTJ 12b, the top electrode 12c and the contact hole 26 are all circular. The diameter of the first contact hole 26 is smaller than the diameter of the top electrode 12c. The boundary of the first contact hole 26 does not exceed the boundary of the top electrode 12c. Furthermore, the diameters of the top electrode 12c, the diameter of the MTJ 12b and the diameter of the bottom electrode 12a are the same. Since the shapes of the bottom electrode 12a, the MTJ 12b, and the top electrode 12c are the same, only the top electrode 12c is shown in FIG. 4.

FIG. 2B depicts a fabricating method of an MRAM structure according to another preferred embodiment of the present invention. FIG. 2C depicts a fabricating method of an MRAM structure according to yet another preferred embodiment of the present invention. According to different embodiments, the steps in FIG. 2A can be replaced by the steps in FIG. 2B or FIG. 2C. As shown in FIG. 2B, during the first etching E1, the photoresist layer 24 is used as a mask to etch the mask layer 22 in the memory region M, the second hard mask 20, and the first hard mask 18 to form numerous first preliminary contact holes 26a and to etch the mask layer 22 in the logic circuit region L, the second hard mask 20, the first hard mask 18 and the first dielectric layer 10 to form the second contact hole 28, wherein all of the first preliminary contact holes 26a are not in the first dielectric layer 10. Then, the steps in FIG. 3 are performed to completely remove the photoresist layer 24 and mask layer 22. After that, the second etching E2 is performed by taking the second hard mask 20 as a mask to etch the first hard mask 18 and the first dielectric layer 10 at a bottom of each of the first preliminary contact holes 26a to form first contact holes 26 and to etch the first dielectric layer 10 in the logic circuit region L to form the trench 30.

It should be noted that since the second hard mask 20 is titanium nitride, only the etchant used in the first etching E1 can etch titanium nitride. Therefore, the second hard mask 20 must be patterned during the first etching E1. In this way, the steps in FIG. 3 can use the second hard mask 20 as a mask, to etch the first hard mask 18 under the second hard mask 20.

The differences between the steps in FIG. 2C and FIG. 2B are described as follows. In the FIG. 2C, during the first etching E1, besides etching the mask layer 22 in the memory region M, the second hard mask 20, and the first hard mask 18, the first dielectric layer 10 are also etched during the first etching E1. However, by performing the steps in FIG. 2C, the depth of the first preliminary contact hole 26b is not deep enough to expose the top electrode 12c. After that, steps in FIG. 3 are performed to complete the trench 30 and the first contact hole 26.

Please refer to FIG. 5 and FIG. 6A. FIG. 5 shows steps in continuous of steps in FIG. 3. FIG. 6A depicts a top view of FIG. 5 according to a preferred embodiment of the present invention. As shown in FIG. 5 and FIG. 6A, a conductive material is formed to fill each of the first contact holes 26, the trench 30 and the second contact hole 28 to form numerous conductive plugs 32 and a first metal interconnect structure 34. The conductive material can be a single layer or multiple layers. The conductive material preferably includes tungsten, tungsten nitride, copper, tantalum nitride, tantalum, titanium or titanium nitride. Each conductive plug 32 contacts one top electrode 12c. When seeing along the vertical direction Y, the diameter of the conductive plug 32 is smaller than the diameter of the MTJ 12b. One conductive plug 32 overlaps only one MRAM 12. In addition, all MRAMs 12 are arranged in an array.

FIG. 6B shows a top view of FIG. 5 according to another preferred embodiment of the present invention. As shown in FIG. 6B, in this embodiment, MRAMs 12 in different columns are arranged in a staggered manner.

FIG. 7 shows steps in continuous of the steps in FIG. 5. As shown in FIG. 7, a second dielectric layer 36 is formed to cover the memory region M and the logic circuit region L of the first dielectric layer 10. The second dielectric layer 36 is preferably a material with a low dielectric constant, such as SiOC:H or fluorosilicon glass (FSG). After that, a second metal interconnect structure 38 and a third metal interconnect structure 40 are formed. The second metal interconnect structure 38 is embedded in the logic circuit region L of the second dielectric layer 36, and the third metal interconnect structure 40 is embedded in the memory region M of the second dielectric layer 36. The second metal interconnect structure 38 contacts the first metal interconnect structure 34. The third metal interconnect structure 40 contacts the conductive plug 32. The top surface of the third metal interconnect structure 40 is aligned with the top surface of the second metal interconnect structure 38. In details, the second metal interconnect structure 38 and the third metal interconnect structure 40 are both dual damascene structures. The second metal interconnect structure 38 and the third metal interconnect structure 40 respectively preferably include copper, tantalum nitride, tantalum, titanium or titanium nitride. Now, an MRAM structure 100 of the present invention is completed.

As shown in FIG. 6A and FIG. 7, an MRAM structure 100 includes a first dielectric layer 10. The first dielectric layer 10 is divided into a memory region M and a logic circuit region L. An MRAM 12 is embedded in the memory region M of the first dielectric layer 10. MRAM 12 includes a bottom electrode 12a, an MTJ 12b and a top electrode 12c stacked in sequence from bottom to top. A spacer 16 surrounds and contacts the MRAM 12. A conductive plug 32 is disposed on the top electrode 12c and contacts the top electrode 12c. A vertical direction Y is defined as a direction from the top electrode 12c to the bottom electrode 12a. When seeing along the vertical direction Y, as shown in FIG. 6A, the bottom electrode 12a, the MTJ 12b, the top electrode 12c and the conductive plug 32 are all circular. The diameter of the bottom electrode 12a, the diameter of the MTJ 12b and the diameter of the top electrode 12c are the same. When viewing along the vertical direction Y, the diameter of the conductive plug 32 is smaller than the diameter of the MTJ 12b. The conductive plug 32 does not exceed the boundary of the top electrode 12c and the boundary of MTJ 12b. Since the top electrode 12c, the MTJ 12b and the bottom electrode 12a have the same diameter and the same shape, and when seeing along the vertical direction Y, the top electrode 12c, the MTJ 12b and the bottom electrode 12a completely overlap with each other, in FIG. 6A, only the MTJ 12b is drawn to represent the positions of the top electrode 12c and the bottom electrode 12a. Furthermore, when seeing along the vertical direction Y, one conductive plug 32 overlaps only one MRAM 12.

A first metal interconnect structure 34 is embedded in the logic circuit region L of the first dielectric layer 10. The first metal interconnect structure 34 includes a contact plug 34a and a conductive line 34b. The conductive line 34b is disposed on the contact plug 32a. The top surface of the conductive line 34b is aligned with the top surface of the conductive plug 32. Furthermore, when seeing along the vertical direction Y, the conductive line 34b is rectangular. The material of the conductive plug 32 is the same as the material of the first metal interconnect structure 34. The material of the conductive plug 32 and the material of the first metal interconnect structure 34 may include tungsten, tungsten nitride, copper, tantalum nitride, tantalum, titanium, or titanium nitride. The conductive plug 32 and the first metal interconnect structure 34 may include a single layer of material or multiple layers of material. The first metal interconnect structure 34 is preferably a dual damascene structure.

A second dielectric layer 36 covers the memory region M and the logic circuit region L of the first dielectric layer 10. A second metal interconnect structure 38 is embedded in the logic circuit region L of the second dielectric layer 36. The second metal interconnect structure 38 contacts the first metal interconnect structure 34. A third metal interconnect structure 40 is embedded in the memory region M of the second dielectric layer 36. The third metal interconnect structure 40 contacts the conductive plug 32. The top surface of the third metal interconnect structure 40 is aligned with the top surface of the second metal interconnect structure 38. The second metal interconnect structure 38 and the third metal interconnect structure 40 are both dual damascene structures. The second metal interconnect structure 38 and the third metal interconnect structure 40 preferably include copper, tantalum nitride, tantalum, titanium or titanium nitride.

As shown in FIG. 2A and FIG. 4, the diameter of the first contact hole 26 is intentionally made to become smaller than the diameter of the top electrode 12c, and the first contact hole 26 does not exceed the boundary of the top electrode 12c. Therefore, when the first dielectric layer 10 is etched to form the first contact hole 26, the spacer 16 surrounding the MTJ 12b is not etched. In this way, the spacer 16 can be guaranteed to cover the sidewall of the MTJ 12b completely. Accordingly, when performing the second etching E2 in FIG. 3, the MTJ 12b will not be damaged by the etchant.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A magnetoresistive random access memory (MRAM) structure, comprising:
a first dielectric layer, wherein the first dielectric layer is divided into a memory region and a logic circuit region;
an MRAM embedded in the memory region of the first dielectric layer, wherein the MRAM comprises a bottom electrode, a magnetic tunnel junction (MTJ) and a top electrode stacked in sequence from bottom to top;
a conductive plug disposed on the top electrode and contacting the top electrode, wherein a diameter of the conductive plug is smaller than a diameter of the MTJ, and the conductive plug overlaps only one MRAM; and
a first metal interconnect structure embedded in the logic circuit region of the first dielectric layer, wherein the first metal interconnect structure comprises a contact plug and a conductive line, the conductive line is disposed on the contact plug, and a top surface of the conductive line is aligned with a top surface of the conductive plug.

2. The MRAM structure of claim 1, wherein a vertical direction is defined as a direction from the top electrode to the bottom electrode, when seeing along the vertical direction, the bottom electrode, the MTJ, the top electrode and the conductive plug are all circular.

3. The MRAM structure of claim 2, wherein when seeing along the vertical direction, the conductive plug does not exceed a boundary of the top electrode.

4. The MRAM structure of claim 2, wherein when seeing along the vertical direction, the conductive line is rectangular.

5. The MRAM structure of claim 1, wherein a shape of the bottom electrode, a shape of the MTJ and a shape of the top electrode are the same.

6. The MRAM structure of claim 1, wherein the conductive plug and the first metal interconnect structure are made of the same material.

7. The MRAM structure of claim 1, further comprising:
a second dielectric layer covering the memory region and the logic circuit region of the first dielectric layer;
a second metal interconnect structure embedded in the logic circuit region of the second dielectric layer, wherein the second metal interconnect structure contacts the first metal interconnect structure; and
a third metal interconnect structure embedded in the memory region of the second dielectric layer, wherein the third metal interconnect structure contacts the conductive plug, and a top surface of the third metal interconnect structure is aligned with a top surface of the second metal interconnect structure.

8. A fabricating method of a magnetoresistive random access memory (MRAM) structure, comprising:
providing a first dielectric layer, wherein the first dielectric layer is divided into a memory region and a logic circuit region, an MRAM is embedded in the memory region of the first dielectric layer, and the MRAM comprises a bottom electrode, a magnetic tunnel junction (MTJ) and a top electrode stacked in sequence from bottom to top;
etching the first dielectric layer to form a first contact hole and a second contact hole in the first dielectric layer, wherein the first contact hole is disposed in the memory region and the top electrode is exposed through the first contact hole, the second contact hole is disposed in the logic circuit region, a diameter of the first contact hole is smaller than a diameter of the top electrode, and a boundary of the first contact hole does not exceed a boundary of the top electrode;
etching the first dielectric layer to form a trench in the logic circuit region of the first dielectric layer, wherein the trench is connected to the second contact hole, the trench is disposed on the second contact hole; and
forming a conductive material to fill the first contact hole, the trench and the second contact hole to form a conductive plug and a first metal interconnect structure, wherein the conductive plug contacts the top electrode.

9. The fabricating method of an MRAM structure of claim 8, wherein steps of forming the first contact hole, the second contact hole and the trench comprise:
forming a first hard mask and a second hard mask in sequence to cover the first dielectric layer;
patterning the second hard mask to form a first opening in the second hard mask in the logic circuit region;
after patterning the second hard mask, forming a mask layer and a photoresist layer to cover the second hard mask from bottom to top, wherein the mask layer fills the first opening;
patterning the photoresist layer to form a second opening and a third opening in the photoresist layer, wherein the second opening corresponds to the MRAM, and the third opening corresponds to the first opening;
after patterning the photoresist layer, etching the mask layer, the second hard mask, the first hard mask and the first dielectric layer to form the first contact hole in the first dielectric layer and the second contact hole by taking the photoresist layer as a first mask;
completely removing the photoresist layer and the mask layer; and
after forming the first contact hole and the second contact hole, etching the first dielectric layer to form the trench in the logic circuit region of the first dielectric layer by taking the second hard mask as a second mask.

10. The fabricating method of an MRAM structure of claim 8, wherein steps of forming the first contact hole, the second contact hole and the trench comprise:
forming a first hard mask and a second hard mask in sequence to cover the first dielectric layer;
patterning the second hard mask to form a first opening in the second hard mask in the logic circuit region;
after patterning the second hard mask, forming a mask layer and a photoresist layer to cover the second hard mask from bottom to top, wherein the mask layer fills the first opening;
patterning the photoresist layer to form a second opening and a third opening in the photoresist layer, wherein the second opening corresponds to the MRAM, and the third opening corresponds to the first opening;
after patterning the photoresist layer, taking the photoresist layer as a first mask to etch the mask layer in the memory region, the second hard mask, and the first hard mask to form a first preliminary contact hole and to etch the mask layer in the logic circuit region, the second hard mask, the first hard mask and the first dielectric layer to form the second contact hole, wherein the first preliminary contact hole is not in the first dielectric layer;
completely removing the photoresist layer and the mask layer; and
after forming the first preliminary contact hole and the second contact hole, taking the second hard mask as a second mask to etch the first hard mask and the first dielectric layer at a bottom of the first preliminary contact hole to form the first trench and to etch the first dielectric layer in the logic circuit region to form the trench.

11. The fabricating method of an MRAM structure of claim 8, wherein a vertical direction is defined as a direction from the top electrode to the bottom electrode, when seeing along the vertical direction, the bottom electrode, the MTJ, the top electrode and the conductive plug are all circular.

12. The fabricating method of an MRAM structure of claim 8, wherein a top surface of the first metal interconnect structure is aligned with a top surface of the conductive plug.

13. The fabricating method of an MRAM structure of claim 8, wherein the conductive plug overlaps only one MRAM.

14. The fabricating method of an MRAM structure of claim 8, further comprising:
forming a second dielectric layer covering the memory region and the logic circuit region of the first dielectric layer;
forming a second metal interconnect structure embedded in the logic circuit region of the second dielectric layer, wherein the second metal interconnect structure contacts the first metal interconnect structure; and
forming a third metal interconnect structure embedded in the memory region of the second dielectric layer, wherein the third metal interconnect structure contacts the conductive plug, and a top surface of the third metal interconnect structure is aligned with a top surface of the second metal interconnect structure.
